(19) United States
(12) Patent Application Publication
(10) Pub. No.: US 2008/0146039 A1
(43) Pub. Date: Jun. 19, 2008

(54) METHOD TO REDUCE PLASMA CHARGE DAMAGE FROM HIGH DENSITY PLASMA CHEMICAL VAPOR DEPOSITION (HDP-CVD) PROCESS

(76) Inventors: Daewon Yang, Hopewell Junction, NY (US); Jeffery B. Maxson, New Windsor, NY (US); Ann N. McDonald, New Windsor, NY (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/611,212

(22) Filed: Dec. 15, 2006

(51) Int. Cl. H01L 21/283

(52) U.S. Cl. 438/758; 257/E21.159

(57) ABSTRACT

A method of processing wafers within a high density plasma chemical vapor deposition chamber comprises setting a plasma charge level within the chamber at a zero power level and, while the plasma charge level within the chamber is at the zero power level, moving a wafer into the chamber. Then, the method sets the plasma charge level to a second power level higher than zero after the wafer is moved into the chamber and performs a chemical vapor deposition process on the wafer within the chamber. After performing the chemical vapor deposition process, the method moves the wafer to a non-plasma region within the chamber. Then, after moving the wafer to the non-plasma region within the chamber, the method again sets the plasma charge level within the chamber at the zero power level. Next, after setting the plasma charge level within the chamber at the zero power level, the method opens the door of the chamber and, while the plasma charge level within the chamber is at the zero power level, the method removes the wafer from the chamber through the door of the chamber.

### FIELD OF THE INVENTION

The embodiments of the invention generally relate to (plasma) chemical vapor deposition processing, and more particularly to a method that reduces plasma charging damage during such processing.

### DESCRIPTION OF THE RELATED ART

Conventional systems deposit materials on wafers (such as semiconductor wafers) within sealed deposition chambers. Such chambers include an electrostatic chuck that holds the wafer during such deposition processing. A high density plasma is generated within the chamber during such deposition processing. One problem that is encountered during such deposition processing is that the wafers can be damaged by various electrical charges that can result from the deposition process.

During conventional deposition processing, the plasma is on at a high power level during the chemical vapor deposition process. While the wafer is loaded into or unloaded from the deposition chamber, the plasma remains on at a lower power level (idle power level) in order to keep the deposition chamber within an acceptable temperature range. If the deposition chamber becomes too cool, foreign matter can condense (or film can take from the chamber wall due to thermal cycling) and contaminate the deposition chamber, necessitating an undesirable cleaning process.

### SUMMARY

In view of the foregoing, an embodiment of the invention provides a method of processing wafers within a high density plasma chemical vapor deposition chamber. The method comprises setting a plasma charge level within the chamber at a zero power level and, while the plasma charge level within the chamber is at the zero power level, moving a wafer into the chamber. Then, the method sets the plasma charge level to a second power level higher than zero after the wafer is moved into the chamber and performs a chemical vapor deposition process on the wafer within the chamber. The second power level comprises a power level suitable for performing high density plasma chemical vapor deposition processing. After performing the chemical vapor deposition process, the method moves the wafer to a non-plasma region within the chamber. Then, after moving the wafer to the non-plasma region within the chamber, the method again sets the plasma charge level within the chamber at the zero power level. Next, after setting the plasma charge level within the chamber at the zero power level, the method opens the door of the chamber and, while the plasma charge level within the chamber is at the zero power level removes the wafer from the chamber through the door of the chamber. During the method, the plasma charge level within the chamber is set at the zero power level, for no more than two minutes. If there are no following wafers (products) within two minutes, then the chamber condition is to set to an idle plasma power level (above zero power, but less than the second power level) while waiting for the next product/process.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a flow diagram illustrating embodiments of the invention; and

FIG. 2 is a schematic diagram of a deposition chamber.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

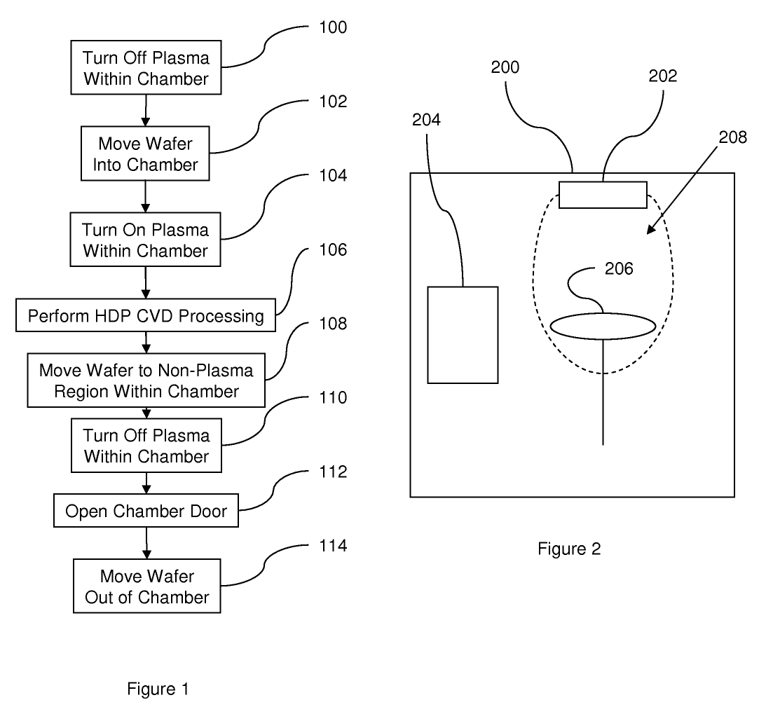

A method of processing wafers within a high density plasma chemical vapor deposition chamber 200 (FIG. 2) is shown in flowchart from in FIG. 1. The method turns off the plasma generator 202 within the chamber, thereby setting the plasma charge level within the chamber at a zero power level (item 100) and, while the plasma charge level within the chamber is at the zero power level, moves the wafer into the chamber (item 102). Then, the method turns on the plasma, thereby setting the plasma charge level to a second power level higher than zero (item 104) after the wafer is moved into the chamber and performs the high density plasma chemical vapor deposition (HDP CVD) process on the wafer within the chamber (item 106). The second power level comprises a power level suitable for performing high density plasma chemical vapor deposition processing.

After performing the chemical vapor deposition process, the method moves the wafer to a non-plasma region within the chamber (item 108). For example, the chuck holding the wafer 206 can be lowered outside the plasma generation region 208 that is formed by the plasma generator 202. Then, after moving the wafer to the non-plasma region within the chamber, the method again turns off the plasma so as to set the plasma charge level within the chamber at the zero power level (item 110). Next, after setting the plasma charge level within the chamber at the zero power level, the method opens the door of the chamber (item 112) and, while the plasma charge level within the chamber is at the zero power level, the method removes the wafer from the chamber through the door of the chamber (item 114). During the method, the plasma charge level within the chamber is set at the zero power level for no more than two minutes. If there are no following wafers (products) within two minutes, then the chamber condition is to set to an idle plasma power level (above zero power, but less than the second power level) while waiting for the next product/process.

The embodiments presented herein provide a manufacturing process that allows high density plasma chemical vapor deposition of nitride films to take place with a minimum amount of plasma charging damage. This increases reliability and improves yield.

A large amount of charge damage occurs from charges between the chamber door (gate valve) 204 and the opposite side of the wafer (across wafer charge damage). While conventional methodologies reduce the plasma charge to an idle voltage, this plasma is still above a zero level voltage and produces charge within the chamber. To the contrary, the present embodiments completely turn off the plasma generator 202 producing a zero power (no plasma charge) within the chamber during times when the wafer is moved into and removed from the chamber.

Even more specifically, the embodiments herein turn the plasma off before the chamber door 204 is opened. Further, the embodiments herein can move the wafer outside the plasma region 208 within the chamber (move the wafer to a non-plasma region within the chamber) by lowering the chuck within the chamber before the plasma is turned off to minimize plasma contact during any instability that may occur while the plasma is being turned off.

Since the plasma is the only heat source for maintaining the chamber in an elevated temperature condition (an elevated temperature is required to minimize the formation of foreign matter particles within the chamber) embodiments herein do not turn off the plasma for more than two minutes at a time. If the plasma was powered off for more than two minutes, the chamber would cool down to a point that could cause particles to form which would necessitate an undesirable cleaning of the chamber.

With embodiments herein, plasma charging damage can be further reduced by allowing the wafer to cool somewhat before the wafer is removed from the processing chamber. The cooling can be achieved simply by turning the clamping voltage on (about 200-1000 V range), or by clamping with a backside cooling gas. The cooling process can be performed in concert with turning the plasma off or it can be performed while leaving the plasma on. There is less chance of plasma damage as the wafer cools. Further, if the wafer is still hot, a non-hydrogen inert gas (Ar, N₂, He, etc.) plasma can be used in conjunction with the foregoing to reduce charging damage when compared to a hydrogen gas plasma. Such non-hydrogen gas plasma can be used before and after the deposition processing.

Therefore, as shown above, the invention provides a method which substantially reduces wafer damage that can occur from the charge associated with plasma by shutting the plasma off (setting power to a zero level) before the wafer is placed into, or removed from the chamber.

The embodiments of the invention can take the form of an entirely hardware embodiment, an entirely software embodiment or an embodiment including both hardware and software elements. In a preferred embodiment, the invention is implemented in software, which includes but is not limited to firmware, resident software, microcode, etc.

Furthermore, the embodiments of the invention can take the form of a computer program product accessible from a computer-usable or computer-readable medium providing program code for use by or in connection with a computer or any instruction execution system. For the purposes of this description, a computer-usable or computer readable medium can be any apparatus that can comprise, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk—read only memory (CD-ROM), compact disk—read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output (I/O) devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A method of processing wafers within a high density plasma chemical vapor deposition chamber, said method comprising:
setting a plasma charge level within said chamber at a zero power level;
while said plasma charge level within said chamber is at said zero power level, moving a wafer into said chamber;
setting said plasma charge level to a second power level higher than zero after said wafer is moved into said chamber;
performing a chemical vapor deposition process on said wafer within said chamber;
after performing said chemical vapor deposition process, setting said plasma charge level within said chamber at said zero power level; and
while said plasma charge level within said chamber is at said zero power level, removing said wafer from said chamber.

2. In the method according to claim 1, wherein said second power level comprises a power level suitable for performing high density plasma chemical vapor deposition processing.

3. The method according to claim 1, wherein, during said method, said plasma charge level within said chamber is set at said zero power level for no more than two minutes.

4. A method of processing wafers within a high density plasma chemical vapor deposition chamber, said method comprising:
setting a plasma charge level within said chamber at a zero power level;
while said plasma charge level within said chamber is at said zero power level, moving a wafer into said chamber;
setting said plasma charge level to a second power level higher than zero after said wafer is moved into said chamber;
performing a chemical vapor deposition process on said wafer within said chamber;
after performing said chemical vapor deposition process, moving said wafer to a non-plasma region within said chamber;
after moving said wafer to said non-plasma region within said chamber, setting said plasma charge level within said chamber at said zero power level;
after setting said plasma charge level within said chamber at said zero power level, opening a door of said chamber; and
while said plasma charge level within said chamber is at said zero power level, removing said wafer from said chamber through said door of said chamber.

5. In the method according to claim 4, wherein said second power level comprises a power level suitable for performing high density plasma chemical vapor deposition processing.

6. The method according to claim 4, wherein, during said method, said plasma charge level within said chamber is set at said zero power level for no more than two minutes.
